(19) United States
(12) Patent Application Publication
(10) Pub. No.: US 2020/0116768 A1
(43) Pub. Date: Apr. 16, 2020

(54) SOCKET WITH POWER DISPLAY FUNCTION

(71) Applicants: Shaopei WANG, Shenzhen (CN); Zezhi LI, Shenzhen (CN); Mingli WU, Shenzhen (CN); Mingwei WANG, Shenzhen (CN)

(72) Inventors: Shaopei WANG, Shenzhen (CN); Zezhi LI, Shenzhen (CN); Mingli WU, Shenzhen (CN); Mingwei WANG, Shenzhen (CN)

(21) Appl. No.: 16/260,062

(22) Filed: Jan. 28, 2019

(30) Foreign Application Priority Data
Oct. 16, 2018 (CN) 201821689222.9

(51) Int. Cl. G01R 21/133; H01R 13/66; G01R 13/40

(52) U.S. Cl. CPC G01R 21/1331; G01R 13/403; H01R 13/665

(57) ABSTRACT

A socket with a power display function comprises a socket input terminal, a power measurement chip, a single-chip microcomputer and a display module. The power measurement chip is connected to the socket input terminal through a voltage sampling module and a current sampling module and is used to measure and figure out the voltage, current and power consumption of the socket. The single-chip microcomputer is connected to an output terminal of the power measurement chip, has an output terminal connected to the display module and is used to receive output information of the single-chip microcomputer and to display corresponding information contents according to the received information. The socket can effectively remind users of to save electricity and to use electricity safely.

### BACKGROUND OF THE INVENTION

The invention relates to a socket, in particular to a socket with a power display function.

As indispensable articles in daily life, existing sockets have only one function and cannot fulfill a power measurement and display function, and consequentially, users cannot timely know the actual current power consumption of the sockets. If multiple electric appliances plugged in one socket are used at the same time in the peak period, the total power consumption of the electric appliances on the socket may exceed the rated power of the socket, which will in turn result in potential safety hazards.

### BRIEF SUMMARY OF THE INVENTION

The objective of the invention is to overcome the defects and drawbacks of the prior art by providing a socket with a power display function.

The invention is implemented based on the following technical solution: A socket with a power display function comprises a socket input terminal, a power measurement chip, a single-chip microcomputer and a display module.

The power measurement chip is connected to the socket input terminal through a voltage sampling module and a current sampling module and is used to measure and figure out the voltage, current and power consumption of the socket.

The single-chip microcomputer is connected to an output terminal of the power measurement chip, has an output terminal connected to the display module and is used to receive and process an output signal from the power measurement chip and to output the processed signal to the display module.

The display module is used to receive output information of the single-chip microcomputer and to display corresponding information contents according to the received information.

Preferably, the power measurement chip is of a HLW8012 type, and the voltage sampling module is a resistor voltage division module.

Preferably, the current sampling module fulfills current sampling through a high-precision resistor, and the display module is a LCD display module or digital display module.

The socket of the invention is able to display the parameters such as power consumption, operating current or operating voltage in work so that users can timely know the current power consumption condition of the socket and can be effectively reminded to save electricity and to use electricity safely.

### BRIEF DESCRIPTION OF THE DRAWINGS

FIG. 1 is a circuit diagram of a socket in the embodiment of the invention.

### REFERENCE SIGNS

1—voltage sampling module, 2—power measurement chip, 3—current sampling module, 4—single-chip microcomputer, 5—display module.

### DETAILED DESCRIPTION OF THE INVENTION

The invention is further expounded below with reference to the accompanying drawings and specific embodiments so that those skilled in this field can have a better understanding of the invention.

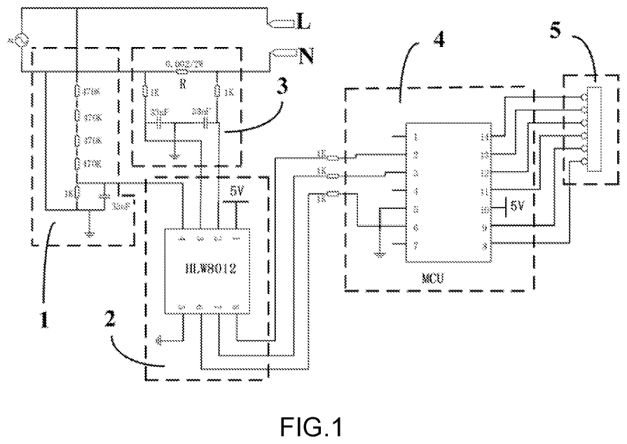

As shown in FIG. 1, a socket with a power display function comprises a socket input terminal, a power measurement chip 2, a single-chip microcomputer 4 and a display module 5.

The power measurement chip is connected to the socket input terminal through a voltage sampling module 1 and a current sampling module 3 and is used to measure and figure out the voltage, current and power consumption of the socket.

The single-chip microcomputer is connected to an output terminal of the power measurement chip, has an output terminal connected to the display module and is used to receive and process an output signal from the power measurement chip and to output the processed signal to the display module.

The display module is used to receive output information from the single-chip microcomputer and to display corresponding information contents according to the received information.

In a preferred embodiment, the power measurement chip 2 is of an HLW8012 type, the voltage sampling module 1 is a resistor voltage division module, and the current sampling module 3 fulfills current sampling through a high-precision resistor R. As shown in FIG. 1, the socket input terminal comprises a wiring terminal L and a wiring terminal N, the resistor voltage division module has an end connected to the wiring terminal L and an end connected to the wiring terminal N, and the high-precision resistor R is connected between the wiring terminal L and the wiring terminal N in series. In addition, a pin 2 and a pin 3 of the power measurement chip HLW8012 are connected to the current sampling module, a pin 4 of the power measurement chip HLW8012 is connected to the resistor voltage division module, and a pin 6, a pin 7 and a pin 8 of the power measurement chip HLW8012 are connected to the display module. Definitely, power measurement chips of other types can also be adopted in this application, and the specific types of the power measurement chip will not be enumerated herein.

In a specific embodiment, the display module may be an LCD display module or a digital display module. The display module adopted in this embodiment is a functional module in the prior art and will not be described in detail herein.

The circuit operating principle of the socket with a power display function of the invention is briefly described as follows: the voltage at the socket input terminal is divided by the resistor voltage division module and is then transmitted to the pin 4 of the power measurement chip HLW8012, and thus, the voltage at the socket input terminal is measured; the operating current of the socket is sampled by the high-precision resistor R in the current sampling module and is then transmitted to the pin 2 and the pin 3 of the power measurement chip HLW8012, and the power measurement chip HLW8012 internally amplifies a current signal received and calculates the current value. In this way, the voltage and current can be calculated through the power measurement chip HLW8012, and the power consumption of the socket is figured out in terms of current and voltage parameters. After the voltage, current and power consumption of the socket are figured out by the power measurement chip HLW8012, a corresponding pulse signal with a variable duty cycle is output by the output terminal (pin 6 and pin 7) of the power measurement chip HLW8012 to indicate the voltage, current and power consumption of the socket. The single-chip microcomputer figures out corresponding voltage, current and power consumption values according to the duty cycle of the pulse signal received and outputs a corresponding signal to enable the display module to display the corresponding values, and then users can conveniently and timely know the current power utilization condition (parameters such as power consumption, operating current or operating voltage) of the socket and are effectively reminded to save electricity and to use electricity safely.

The above embodiments are preferred implementations of the invention, but are not intended to limit the invention. Any substitutes easily achieved without deviating from the concept of the invention should also fall within the protection scope of the invention.

What is claimed is:

1. A socket with a power display function, comprising a socket input terminal, a power measurement chip, a single-chip microcomputer and a display module, wherein:
the power measurement chip is connected to the socket input terminal through a voltage sampling module and a current sampling module and is used to measure and figure out a voltage, current and power consumption of the socket;
the single-chip microcomputer is connected to an output terminal of the power measurement chip, has an output terminal connected to the display module and is used to receive and process an output signal from the power measurement chip and to output the processed signal to the display module;
the display module is used to receive output information of the single-chip microcomputer and to display corresponding information contents according to the received information.

2. The socket according to claim 1, wherein the power measurement chip is of a HLW8012 type.

3. The socket according to claim 2, wherein the voltage sampling module is a resistor voltage division module.

4. The socket according to claim 3, wherein the current sampling module fulfills current sampling through a high-precision resistor.

5. The socket according to claim 4, wherein a pin 2 and a pin 3 of the power measurement chip HLW8012 are connected to the current sampling module, a pin 4 of the power measurement chip HLW8012 is connected to the resistor voltage division module, and a pin 6, a pin 7 and a pin 8 of the power measurement chip HLW8012 are connected to the display module.

6. The socket according to claim 1, wherein the display module is an LCD display module or a digital display module.
